(19) United States
(12) Patent Application Publication
(10) Pub. No.: US 2015/0377923 A1
(43) Pub. Date: Dec. 31, 2015

(54) TEST SOCKET WITH HIGH DENSITY CONDUCTION SECTION

(71) Applicant: ISC CO., LTD., Seongnam-si, Gyeonggi-do (KR)

(72) Inventor: Jae Hak LEE, Seongnam-si (KR)

(21) Appl. No.: 14/766,002

(22) PCT Filed: Feb. 18, 2014
(86) PCT No.: PCT/KR2014/001313

§ 371 Date: Aug. 5, 2015

(30) Foreign Application Priority Data
Feb. 19, 2013 (KR) 10-2013-0017665
Feb. 28, 2013 (KR) 10-2013-0022124

(51) Int. Cl. G01R 1/04

(52) U.S. Cl. CPC G01R 1/0416

(57) ABSTRACT

Provided is a test socket having high-density conduction sections. The test socket is configured to be disposed between a device to be tested and a test apparatus for electrically connecting terminals of the device and pads of the test apparatus. The test socket includes: an elastic conductive sheet including first conduction sections and an insulative support section, the first conduction sections being disposed at positions corresponding to the terminals of the device and formed by arranging a plurality of first conductive particles in an elastic material in a thickness direction of the first conduction sections, the insulative support section supporting the first conduction sections and insulating the first conduction sections from each other; a support sheet attached to a top surface of the elastic conductive sheet and including penetration holes at positions corresponding to the terminals of the device; and second conduction sections disposed in the penetration holes of the support sheet and formed by arranging a plurality of second conductive particles in an elastic material in a thickness direction of the second conduction sections. The second conductive particles are arranged more densely than the first conductive particles, and the penetration holes have an upper diameter that is greater than a lower diameter thereof.

### TECHNICAL FIELD

The inventive concept relates to a test socket having high-density conduction sections, and more particularly, to a test socket having durable high-density conduction sections capable of making reliable electric contact with terminals of a device to be tested.

### BACKGROUND ART

In general, when testing electrical characteristics of a device, the device is stably electrically connected to a test apparatus. A test socket is generally used for connecting the device to be tested and the test apparatus.

The function of such a test socket is to connect terminals of a device to be tested to pads of a test apparatus so as to allow two-way transmission of electrical signals therebetween. To this end, an elastic conductive sheet or pogo pins are used in a test socket as contact parts. An elastic conductive sheet is used to bring elastic conduction sections into contact with terminals of a device to be tested, and pogo pins in which springs are disposed are used to connect a device to be tested and a test apparatus while buffering any mechanical impact that may occur when making the connection. Such elastic conductive sheets or pogo pins are used in most test sockets.

FIG. 1 illustrates an exemplary test socket 20 of the related art. The test socket 20 includes: conductive silicone sections 8 formed at positions to which ball leads 4 of a ball grid array (BGA) semiconductor device 2 may be placed; and an insulative silicone section 6 formed in a region not making contact with the ball leads (lead terminals) 4 of the semiconductor device 2 for supporting the conductive silicone sections 8. The conductive silicone sections 8 electrically connect the lead terminals 4 of the semiconductor device 2 to contact pads 10 of a socket board 12 for testing the semiconductor device 2, and conductive rings 7 are mounted on top surfaces of the conductive silicone sections 8.

The test socket 20 may be useful for an inspection apparatus making contact with a semiconductor device by pushing the semiconductor device toward the inspection apparatus. In addition, since the conductive silicone sections 8 are individually pushed, it may be easy to perform a test process according to the flatness of peripheral devices. In other words, the conductive silicone sections 8 have improved electric characteristics. Furthermore, the conductive rings 7 prevent spreading of the conductive silicone sections 8 when the conductive silicone sections 8 are pushed by the lead terminals 4 of the semiconductor device 2, and thus the conductive silicone sections (contacts) 8 may be less deformed and thus stably used for a long period of time.

FIG. 2 illustrates another exemplary test socket 20 of the related art. Conductive silicone sections 8 electrically connect contact pads 10 of a socket board 12 to lead terminals 4 of a semiconductor device 2 to be tested, and conductors 22 are formed on the top and/or bottom surfaces of the conductive silicone sections 8 by a plating, etching, or coating method.

However, since the conductors 22 formed on the top and bottom surfaces of the conductive silicone sections 8 by the plating, etching, or coating method are relatively rigid, the elasticity of the conductive silicone sections 8 may be lowered as compared with the case of not using the conductors 22. Therefore, the conductive silicone sections 8 connecting the lead terminals 4 of the semiconductor device 2 and the contact pads 10 of the socket board (test board) 12 may be less elastic. Furthermore, the conductors 22 formed by the plating, etching, or coating method, the semiconductor device 2, or the contact pads 10 of the test board 12 may be damaged if contacting actions are frequently carried out, and contaminants may be accumulated thereon.

To address such problems, a test socket shown in FIGS. 3A and 3B has been proposed. The test socket includes: conductive silicone sections 8 formed of a mixture of silicone and conductive metal powder and disposed at positions where ball leads 4 of a BGA semiconductor device 2 may be placed; and an insulative silicone section 6 formed in a region not making contact with the ball leads (lead terminal) 4 of the semiconductor device 2 for supporting the conductive silicone sections 8. Conductivity enhancing films 30 and 30′ having a conductive metal powder density greater than that of the conductive silicone sections 8 are formed on the top surfaces (refer to FIG. 3A) and/or bottom surfaces (refer to FIG. 3B) of the conductive silicone sections 8. Therefore, the test socket shown in FIGS. 3A and 3B has improved conductivity.

However, the test socket of the related art may have the following problems.

Although the conductivity of the test socket is improved owing to the conductivity enhancing films 30 and 30′, since the conductivity enhancing films 30 and 30′ protrude from the conductive silicone sections 8, the conductivity enhancing films 30 and 30′ may be easily deformed or damaged by frequent contact with the terminals 4 of the semiconductor device 2.

In particular, the conductivity enhancing films 30 and 30′ may be deformed and broken by frequent contact with the terminals 4.

### DETAILED DESCRIPTION OF THE INVENTIVE CONCEPT

### Technical Problem

The inventive concept provides a test socket including durable high-density conduction sections having improved electric contact characteristics.

### Technical Solution

According to an aspect of the inventive concept, there is provided a test socket having high-density conduction sections and configured to be disposed between a device to be tested and a test apparatus for electrically connecting terminals of the device and pads of the test apparatus, the test socket including: an elastic conductive sheet including first conduction sections and an insulative support section, the first conduction sections being disposed at positions corresponding to the terminals of the device and formed by arranging a plurality of first conductive particles in an elastic material in a thickness direction of the first conduction sections, the insulative support section supporting the first conduction sections and insulating the first conduction sections from each other; a support sheet attached to a top surface of the elastic conductive sheet and including penetration holes at positions corresponding to the terminals of the device; and second conduction sections disposed in the penetration holes of the support sheet and formed by arranging a plurality of second conductive particles in an elastic material in a thickness direction of the second conduction sections, wherein the second conductive particles are arranged more densely than the first conductive particles, and the penetration holes have an upper diameter that is greater than a lower diameter thereof.

The penetration holes may have a downwardly decreasing diameter.

The penetration holes may include: diameter decreasing portions having a downwardly decreasing diameter; and constant diameter portions formed below the diameter decreasing portions and having a constant diameter.

The diameter decreasing portions may have a height that is smaller than that of the constant diameter portions.

The second conductive particles may have an average particle diameter that is smaller than that of the first conductive particles.

An average distance between the second conductive particles may be smaller than an average distance between the first conductive particles.

The support sheet may be formed of a material that is harder than a material used to form the insulative support section.

Separation lines may be formed in the support sheet to provide independency to the second conduction sections neighboring each other.

The separation lines may be grooves or holes formed by cutting the support sheet.

According to another aspect of the inventive concept, there is provided a test socket having high-density conduction sections and configured to be disposed between a device to be tested and a test apparatus for electrically connecting terminals of the device and pads of the test apparatus, the test socket including: an elastic conductive sheet including first conduction sections and an insulative support section, the first conduction sections being disposed at positions corresponding to the terminals of the device and formed by arranging a plurality of first conductive particles in an elastic material in a thickness direction of the first conduction sections, the insulative support section supporting the first conduction sections and insulating the first conduction sections from each other; a support sheet attached to a bottom surface of the elastic conductive sheet and including penetration holes at positions corresponding to the terminals of the device; and second conduction sections disposed in the penetration holes of the support sheet and formed by arranging a plurality of second conductive particles in an elastic material in a thickness direction of the second conduction sections, wherein the second conductive particles are arranged more densely than the first conductive particles, and the penetration holes have a lower diameter that is greater than an upper diameter thereof.

According to another aspect of the inventive concept, there is provided a test socket having high-density conduction sections and configured to be disposed between a device to be tested and a test apparatus for electrically connecting terminals of the device and pads of the test apparatus, the test socket including: an elastic conductive sheet including first conduction sections and an insulative support section, the first conduction sections being disposed at positions corresponding to the terminals of the device and formed by arranging a plurality of first conductive particles in an elastic material in a thickness direction of the first conduction sections, the insulative support section supporting the first conduction sections and insulating the first conduction sections from each other; a support sheet attached to a top surface of the elastic conductive sheet and including first penetration holes at positions corresponding to the terminals of the device; second conduction sections disposed in the first penetration holes of the support sheet and formed by arranging a plurality of second conductive particles in an elastic material in a thickness direction of the second conduction sections; and an elastic part disposed on a top surface of the support sheet and including second penetration holes corresponding to the terminals of the device, the elastic part being formed of a material that is softer than a material used to form the support sheet, wherein the second conductive particles are arranged more densely than the first conductive particles.

The second conductive particles may have an average particle diameter that is smaller than that of the first conductive particles.

An average distance between the second conductive particles may be smaller than an average distance between the first conductive particles.

Separation lines manufactured by formed in the support sheet to provide independency to the second conduction sections neighboring each other.

The material used to form the support sheet may be harder than a material used to form the insulative support section.

The elastic part may be formed of the same material as a material used to form the insulative support section.

The elastic part may be formed of silicone rubber.

The terminals of the device may be insertable into the second penetration holes of the elastic part.

The second conduction sections may protrude from the support sheet and may be inserted into the second penetration holes of the elastic part.

The test socket may further include: a lower support sheet attached to a bottom surface of the elastic conductive sheet and including lower penetration holes at positions corresponding to the terminals of the device; and lower conduction sections disposed in the lower penetration holes of the lower support sheet and formed by arranging a plurality of third conductive particles in an elastic material in a thickness direction of the lower conduction sections, wherein the third conductive particles may be arranged more densely than the first conductive particles.

### Advantageous Effects

According to the inventive concept, since the second conduction sections in which the second conductive particles are densely arranged are supported in the support sheet, the test socket may have improved electric conductivity and durability.

Furthermore, since the second conduction sections of the test socket have an upper diameter that is greater than a lower diameter thereof, terminals of a device to be tested may be easily brought into contact with the second conduction sections.

Furthermore, in the test socket, the soft elastic part is disposed on top of the support sheet. Therefore, terminals of a device to be tested may be less damaged.

### DESCRIPTION OF THE DRAWINGS

FIGS. 1 to 3 are views illustrating test sockets of the related art.

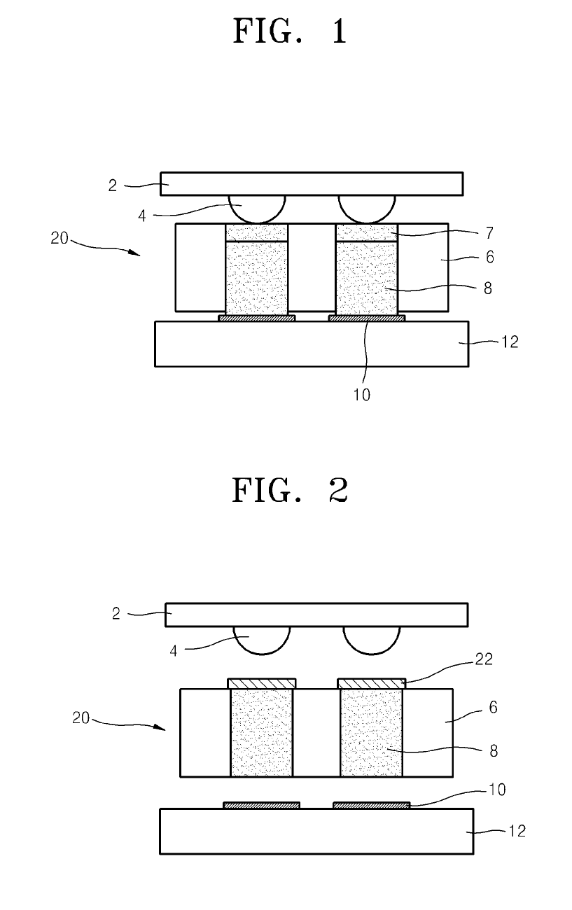

FIG. 4 is a view illustrating a test socket according to an embodiment of the present invention.

FIG. 5 is a plan view illustrating the test socket of FIG. 4.

FIG. 6 is a view illustrating an operational state of the test socket of FIG. 4.

FIGS. 7 to 9 are views illustrating test sockets according to other embodiments of the present invention.

FIG. 10 is a view illustrating a test socket according to another embodiment of the present invention.

FIG. 11 is a view illustrating an operational state of the test socket of FIG. 10.

FIGS. 12 and 13 are views illustrating modification examples of the test socket of FIG. 9.

### MODE OF THE INVENTIVE CONCEPT

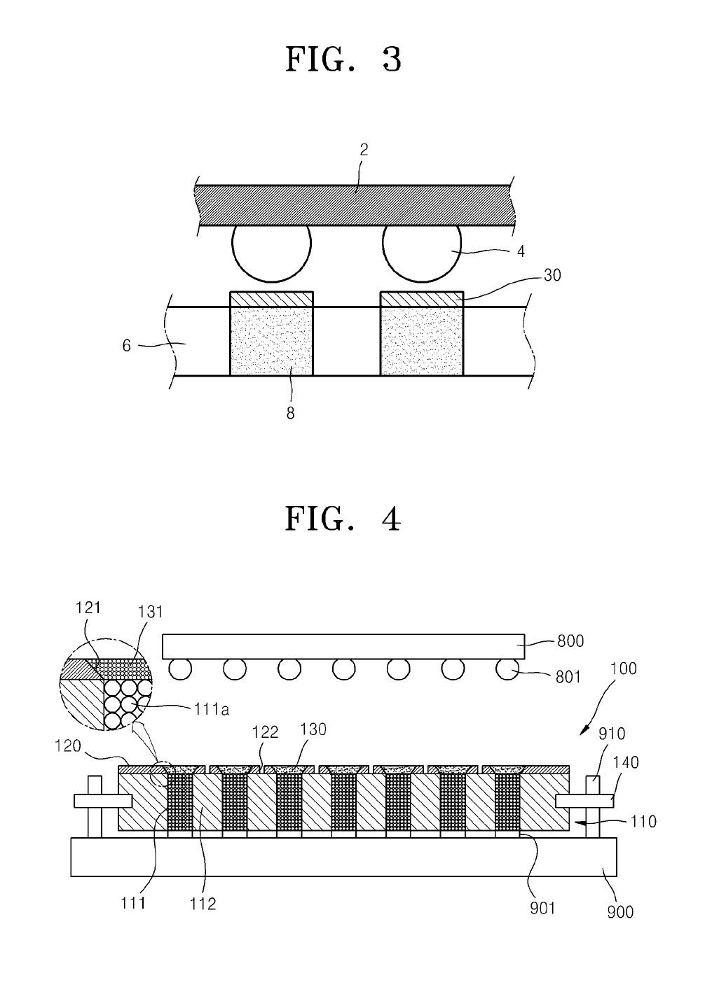

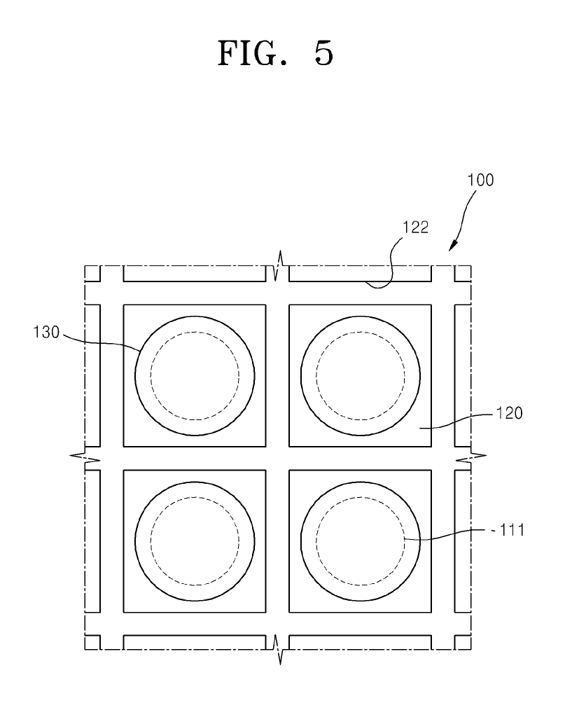

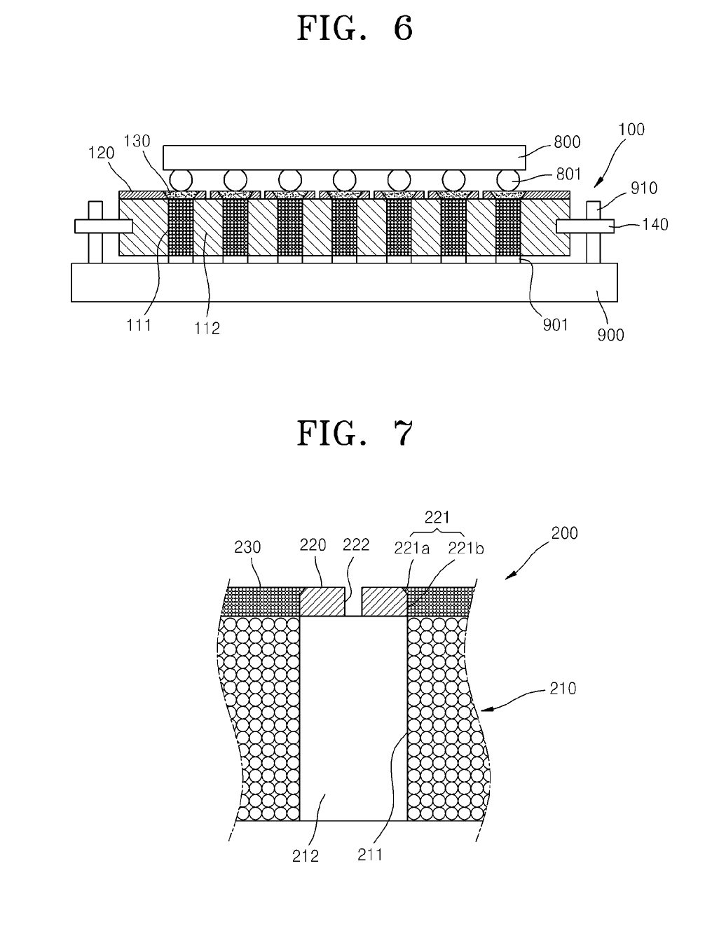

FIGS. 4 to 6 illustrate a test socket 100 according to an embodiment of the present invention. The test socket 100 is disposed between a device 800 to be tested and a test apparatus 900 to electrically connect terminals 801 of the device 800 to pads 901 of the test apparatus 900.

The test socket 100 includes an elastic conductive sheet 110, a support sheet 120, and second conduction sections 130.

The elastic conductive sheet 110 allows electric current to flow in a thickness direction thereof but does not allow electric current to flow in a surface direction thereof perpendicular to the thickness direction. The elastic conductive sheet 110 is elastically compressible to absorb any impact applied by the terminals 801 of the device 800. The elastic conductive sheet 110 includes first conduction sections 111 and an insulative support section 112.

The first conduction sections 111 are arranged at positions corresponding to the terminals 801 of the device 800, and each of the first conduction sections 111 is formed by linearly arranging a plurality of first conductive particles 111a in an elastic material.

For example, the elastic material for forming the first conduction sections 111 may be a heat-resistant, cross-linked polymer. The heat-resistant, cross-linked polymer may be obtained from various curable polymers used to form materials such as liquid silicone rubber. The liquid silicone rubber may be addition-cure or condensation-cure liquid silicone rubber. In the current embodiment, for example, addition-cure liquid silicone rubber may be used. For example, the first conduction sections 111 may be formed using a cured product of a liquid silicone rubber (hereinafter referred to as a cured silicone rubber) having a compression set of 10% or less, 8% or less, or 6% or less, at 150° C. If the compression set of the cured silicone rubber is greater than 10%, the first conductive particles 111a of the first conduction sections 111 may be in disorder after the elastic conductive sheet 110 is repeatedly used at high temperatures, and the conductivity of the first conduction sections 111 may be lowered.

The first conductive particles 111a may be formed by coating magnetic core particles with a highly conductive metal. The highly conductive material may have a conductivity of 5×10⁶ Ω/m or greater at 0° C. The magnetic core particles may have a number average particle diameter of 3 μm to 40 μm. The number average particle diameter of the magnetic core particles is measured by a laser diffraction scattering method. Examples of a material that may be used to form the magnetic core particles may include iron, nickel, cobalt, and materials formed by coating copper or a resin with the metals. The magnetic core particles may be formed of a material having a saturation magnetization of 0.1 Wb/m² or greater, 0.3 Wb/m² or greater, or 0.5 Wb/m². For example, the magnetic core particles may be formed of iron, nickel, cobalt, or an alloy thereof.

Examples of the highly conductive metal for coating the magnetic core particles include gold, silver, rhodium, platinum, and chromium. For example, gold may be used as the highly conductive metal because gold is chemically stable and highly conductive.

The insulative support section 112 supports the first conduction sections 111 and insulates the first conduction sections 111 from each other. The insulative support section 112 may be formed of the same material as the elastic material used to form the first conduction sections 111. However, materials that may be used to form the insulative support section 112 are not limited thereto. Any insulative material having high elasticity may be used to form the insulative support section 112.

The support sheet 120 may be attached to a top surface of the elastic conductive sheet 110. Penetration holes 121 may be formed in the support sheet 120 at positions corresponding to the terminals 801 of the device 800 to be tested. The support sheet 120 supports the second conduction sections 130 (described later in detail). The support sheet 120 may be formed of a material that is harder than the second conduction sections 130. That is, the support sheet 120 may be formed of a material having low elasticity and high strength. For example, the support sheet 120 may be formed of a synthetic resin such as polyimide. However, the support sheet 120 is not limited thereto. For example, the support sheet 120 may be formed of silicone, urethane, or any other elastic material.

The penetration holes 121 of the support sheet 120 may be formed using a laser or through other machining processes. Each of the penetration holes 121 may have an upper diameter that is greater than a lower diameter thereof. For example, the diameter of each of the penetration holes 121 may be gradually reduced in a downward direction. In this case, the terminals 801 of the device 800 may be easily inserted into the penetration holes 121 and brought into contact with the second conduction sections 130. For example, although the device 800 is not precisely moved down to the center of the penetration holes 121, the terminals 801 of the device 800 may be easily brought into contact with the second conduction sections 130. In addition, since the penetration holes 121 have a reversed truncated cone shape, although the terminals 801 are moved to edges of the penetration holes 121, the terminals 801 may be shifted to the centers of the penetration holes 121 (position offsetting).

In addition, the support sheet 120 may include separation lines 122 for providing independency to the second conduction sections 130. The separation lines 122 may be grooves or holes formed in the support sheet 120 by using a laser or cutting tool. If the support sheet 120 is divided by the separation lines 122 as described above, the second conduction sections 130 neighboring each other may be independently moved upward and downward. That is, a second conduction section 130 may not be moved down to a height equal or similar to the height of a neighboring second conduction section 130 when the neighboring second conduction section 130 is moved down. That is, the second conduction sections 130 may be moved independent of each other.

The second conduction sections 130 are disposed in the penetration holes 121 of the support sheet 120. The second conduction sections 130 are formed by arranging a plurality of second conductive particles 131 in a thickness direction of the second conduction sections 130. The elastic material used to form the second conduction sections 130 may be identical or similar to the elastic material used to form the first conduction sections 111. In same cases, the elastic material used to form the second conduction sections 130 may have a higher degree of strength than the elastic material used to form the first conduction sections 111. The amount of the elastic material per unit area of the second conduction sections 130 may be smaller than the amount of the elastic material per unit area of the first conduction sections 111.

The second conductive particles 131 may be formed of a material identical or similar to the material used to form the first conductive particles 111a. However, the second conductive particles 131 may be arranged more densely than the first conductive particles 111a. For example, portions occupied by the second conductive particles 131 in a unit area may be larger than portions occupied by the first conductive particles 111a in a unit area. Therefore, the average distance between the second conductive particles 131 may be smaller than the average distance between the first conductive particles 111a.

For example, the average particle diameter of the second conductive particles 131 may be smaller than that of the first conductive particles 111a. That is, the second conductive particles 131 having an average particle diameter that is smaller than that of the first conductive particles 111a may be densely arranged in the elastic material. The average particle diameter of the second conductive particles 131 may be smaller than that of the first conductive particles 111a by a factor of between 2 and 10.

The second conduction sections 130 may be securely attached to the first conduction sections 111 through the penetration holes 121 of the support sheet 120. In this case, although the terminals 801 of the device 800 are frequently brought into contact with the second conduction sections 130, the second conduction sections 130 may not be easily separated or damaged.

Reference numerals 140 and 910 refer to a metal frame and guide pins. The metal frame 140 is disposed around the elastic conductive sheet 110, and the guide pins 910 protrude upward from the test apparatus 900 so as to be used to align the test socket 100.

According to the current embodiment of the present invention, the test socket 100 may have the following operations and effects.

Referring to FIG. 4, the test socket 100 is placed on the test apparatus 900. In detail, the test socket 100 is placed on the test apparatus 900 in such a manner that the first conduction sections 111 of the elastic conductive sheet 110 may make contact with the pads 901 of the test apparatus 900, respectively. At this time, the terminals 801 of the device 800 are placed above the second conduction sections 130 and are aligned with the second conduction sections 130. Thereafter, the device 800 is moved down to bring the terminals 801 of the device 800 into contact with the second conduction sections 130. After the terminals 801 of the device 800 are securely brought into contact with the second conduction sections 130, the test apparatus 900 applies an electric signal to the device 800 for performing an electric inspection.

The test socket 100 of the present embodiment may provide the following effects.

First, since the second conduction sections 130 making contact with the device 800 are formed of densely arranged conductive particles, a reliable electric connection may be established between the second conduction sections 130 and the device 800. In particular, since the second conduction sections 130 are supported by the support sheet 120, the second conduction sections 130 may maintain their original shapes even after the second conduction sections 130 are repeatedly brought into contact with devices to be tested.

In particular, the second conductive particles 131 are smaller than the first conductive particles 111a and are densely arranged in an elastic material. Since the second conductive particles 131 have a small average particle diameter, the area of point contact between the second conductive particles 131 and the terminals 801 of the device 800 may be large. For example, if the second conductive particles 131 are small and densely arranged, the number of the second conductive particles 131 making contact with the terminals 801 of the device 800 may be increased, and the contact area between the second conductive particles 131 and the terminals 801 of the device 800 may also be increased. Accordingly, the electric connection therebetween may be more reliable.

Furthermore, the penetration holes 121 have an upper diameter that is greater than a lower diameter thereof, and the second conduction sections 130 having a shape corresponding to the shape of the penetration holes 121 are inserted into the penetration holes 121. Therefore, the contact area between the second conduction sections 130 and the device 800 may be increased. In the related art, the first conduction sections 111 and the second conduction sections 130 have the same diameter. However, according to the current embodiment of the present invention, the second conduction sections 130 have an upper diameter that is greater than a lower diameter thereof (that is, the upper diameter of the second conduction sections 130 is greater than the diameter of the first conduction sections 111). Therefore, the terminals 801 of the device 800 may be easily brought into contact with the second conduction sections 130. Furthermore, since the penetration holes 121 have a reversed truncated cone shape, although the terminals 801 of the device 800 are placed on the edges of the penetration holes 121, the terminals 801 may be shifted to the centers of the penetration holes 121.

The test socket 100 of the embodiment of the present invention may be modified as follows.

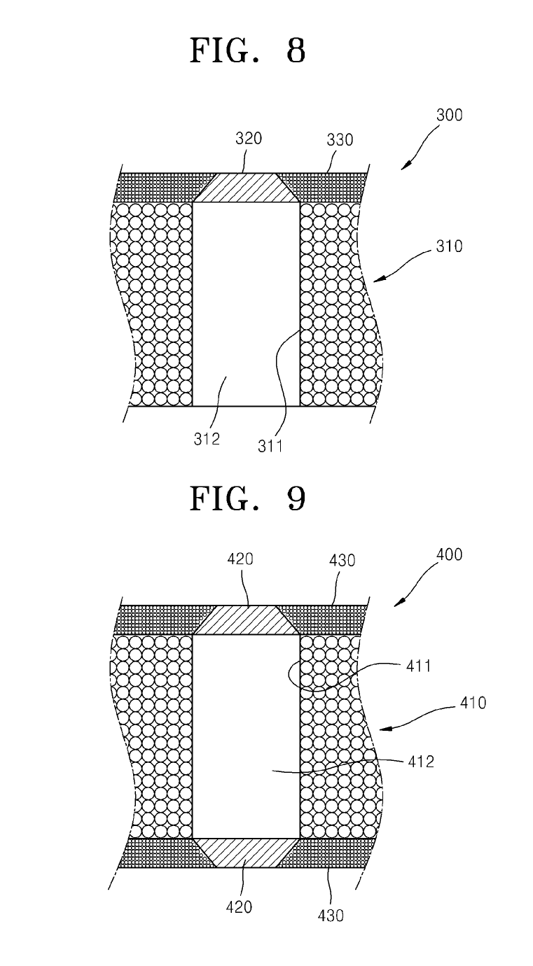

Referring to FIG. 7, the diameter of penetration holes 221 is not constantly reduced. In detail, the penetration holes 221 may include diameter decreasing portions 221a having a downwardly decreasing diameter, and constant diameter portions 221b formed below the diameter decreasing portions 221a and having a constant diameter. The height of the diameter decreasing portions 221a may be smaller than the height of the constant diameter portions 221b. Since the diameter decreasing portions 221a are formed in a top surface of a support sheet 220, terminals 801 of a device 800 may not be damaged even though the terminals 801 of the device 800 are brought into contact with inner surfaces of the penetration holes 221 of the support sheet 220. For example, if upper edges of the penetration holes 221 are angled, the surfaces of the terminals 801 of the device 800 may be damaged if the terminals 801 of the device 800 are brought into contact with the angled upper edges of the penetration holes 221. However, if the penetration holes 221 have tapered upper edges as shown in FIG. 7, the terminals 801 of the device 800 may be less damaged.

In addition, as shown in FIG. 8, a support sheet 320 may not include separation lines, and as shown in FIG. 9, support sheets 420 may be disposed on top and bottom surfaces of an elastic conductive sheet 410. Furthermore, in other embodiments, a support sheet may only be disposed on a bottom surface of an elastic conductive sheet.

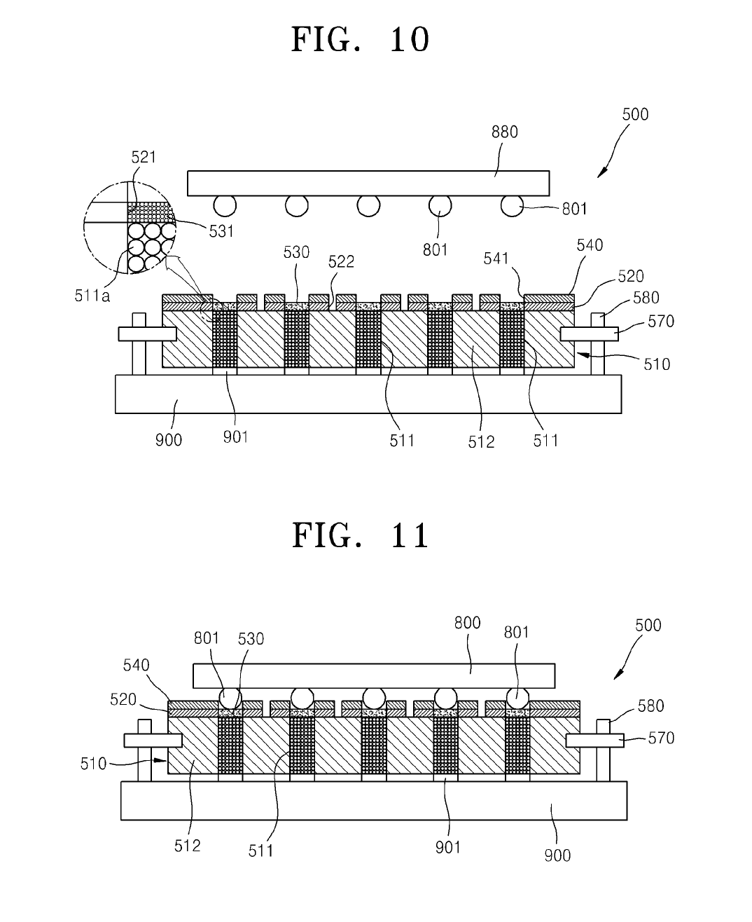

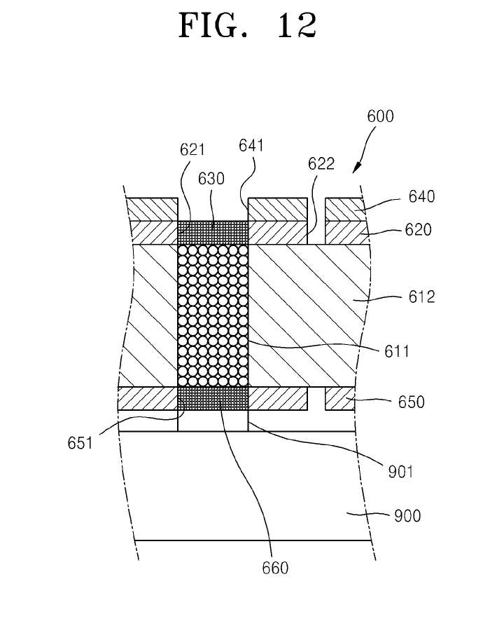

FIGS. 10 and 11 illustrate a test socket 500 according to another embodiment of the present invention.

The test socket 500 includes an elastic conductive sheet 510, a support sheet 520, second conduction sections 530, and an elastic part 540.

The elastic conductive sheet 510 allows electric current to flow in a thickness direction thereof but does not allow electric current to flow in a surface direction thereof perpendicular to the thickness direction. The elastic conductive sheet 510 is elastically compressible to absorb impacts applied by terminals 801 of a device 800 to be tested. The elastic conductive sheet 510 includes first conduction sections 511 and an insulative support section 512.

The first conduction sections 511 are arranged at positions corresponding to the terminals 801 of the device 800, and each of the first conduction sections 511 is formed by linearly arranging a plurality of first conductive particles 51 la in an elastic material.

The elastic material used to form the first conduction sections 511 may be a heat-resistant, cross-linked polymer such as the heat-resistant, cross-linked polymer described in relation to the first conduction sections 111 of the previous embodiment.

Like the first conductive particles 111a of the previous embodiment, the first conductive particles 511a may be formed by coating magnetic core particles with a highly conductive metal.

The insulative support section 512 supports the first conduction sections 511 and insulates the first conduction sections 511 from each other. The insulative support section 512 may be formed of the same material as the elastic material used to form the first conduction sections 511. However, materials that may be used to form the insulative support section 512 are not limited thereto. Any insulative material having high elasticity may be used to form the insulative support section 512.

The support sheet 520 may be attached to a top surface of the elastic conductive sheet 510. First penetration holes 521 may be formed in the support sheet 520 at positions corresponding to the terminals 801 of the device 800 to be tested. The support sheet 520 supports the second conduction sections 530 (described later in detail). The support sheet 520 may be formed of a material that is harder than the second conduction sections 530. For example, the support sheet 520 may be formed of a synthetic resin such as polyimide. However, the support sheet 520 is not limited thereto. For example, the support sheet 520 may be formed of silicone, urethane, or any other elastic material. The first penetration holes 521 of the support sheet 520 may be formed using a laser or through other machining processes.

In addition, the support sheet 520 may include separation lines 522 for providing independency to the second conduction sections 530. The separation lines 522 may be grooves or holes formed in the support sheet 520 using a laser or cutting tool. If the support sheet 520 is divided by the separation lines 522 as described above, the second conduction sections 530 neighboring each other may be independently moved upward and downward. That is, a second conduction section 530 may not be moved down to a height equal or similar to that of a neighboring second conduction section 530 when the neighboring second conduction section 530 is moved down. That is, the second conduction sections 130 may be moved independent of each other.

The second conduction sections 530 are disposed in the first penetration holes 521 of the support sheet 520. The second conduction sections 530 are formed by arranging a plurality of second conductive particles 531 in a thickness direction of second conduction sections. The elastic material used to form the second conduction sections 530 may be identical or similar to the elastic material used to form the first conduction sections 511. In same cases, the elastic material used to form the second conduction sections 530 may have a higher degree of strength than the elastic material used to form the first conduction sections 511. The amount of the elastic material per unit area of the second conduction sections 530 may be smaller than the amount of the elastic material per unit area of the first conduction sections 511.

The second conductive particles 531 may be formed of a material identical or similar to the material used to form the first conductive particles 511a. However, the second conductive particles 531 may be arranged more densely than the first conductive particles 511a. For example, portions occupied by the second conductive particles 531 in a unit area may be larger than portions occupied by the first conductive particles 511a in a unit area. Therefore, the second conductive particles 531 may be densely arranged.

For example, the average particle diameter of the second conductive particles 531 may be smaller than that of the first conductive particles 511a. That is, the second conductive particles 531 having an average diameter that is smaller than that of the first conductive particles 511a may be densely arranged in the elastic material. The average particle diameter of the second conductive particles 531 may be smaller than that of the first conductive particles 511a by a factor of between 2 and 10.

The average distance between the second conductive particles 531 may be smaller than the average distance between the first conductive particles 511a. That is, the second conductive particles 531 may be arranged more densely than the first conductive particles 511a.

The second conduction sections 530 may be securely attached to the first conduction sections 511 through the first penetration holes 521 of the support sheet 520. In this case, although the terminals 801 of the device 800 are frequently brought into contact with the second conduction sections 530, the second conduction sections 530 may not be easily separated or damaged.

The elastic part 540 is disposed on top of the support sheet 520, and second penetration holes 541 are formed in the elastic part 540 at positions corresponding to the positions of the terminals 801 of the device 800. The elastic part 540 may be an elastic sheet that is softer than the support sheet 520. The elastic part 540 may be formed of the same material as that used to form the insulative support section 512 of the elastic conductive sheet 510. For example, the elastic part 540 may be formed of soft silicone rubber. Since the elastic part 540 formed of a thin sheet is disposed on top of the support sheet 520, the terminals 801 of the device 800 may not be damaged or may be less damaged when making contact with the elastic part 540. For example, if the device 800 is directly brought into contact with the support sheet 520 formed of a relatively hard material, the terminals 801 of the device 800 may be damaged. However, since the elastic part 540 formed of a relatively soft material is disposed on top of the support sheet 520, the terminals 801 of the device 800 may not be damaged.

Reference numerals 570 and 580 refer to a metal frame and guide pins. The metal frame 570 is disposed around the elastic conductive sheet 510, and the guide pins 580 protrude upward from a test apparatus 900 so as to be used to align the test socket 500.

According to the current embodiment of the present invention, the test socket 500 may have the following operations and effects.

After the elastic conductive sheet 510 is placed on the test apparatus 900, the device 800 to be tested is placed above the elastic conductive sheet 510. Thereafter, the device 800 is moved down to insert the terminals 801 of the device 800 into the second penetration holes 541 of the elastic part 540. Thereafter, the device 800 is pushed down for firm contact between the terminals 801 of the device 800 and the second conduction sections 530, and the test apparatus 900 applies an electric signal to the device 800 through the first conduction sections 511 and the second conduction sections 530 so as to perform an electric inspection.

The test socket 500 of the current embodiment of the present invention may provide the following effects.

First, since the second conduction sections 530 making contact with the device 800 are formed of densely arranged conductive particles, a reliable electric connection may be established between the second conduction sections 530 and the device 800. In particular, since the second conduction sections 530 are supported by the support sheet 520, the second conduction sections 530 may maintain their original shapes even after the second conduction sections 530 are repeatedly brought into contact with devices to be tested.

In particular, the second conductive particles 531 may be smaller than the first conductive particles 511a and may be densely arranged in an elastic material. Since the second conductive particles 531 have a small average particle diameter, the number of contact points between the second conductive particles 531 and the terminals 801 of the device 800 may be large. For example, if the second conductive particles 531 are small and densely arranged, the number of the second conductive particles 531 making contact with the terminals 801 of the device 800 may be increased, and the contact area between the second conductive particles 531 and the terminals 801 of the device 800 may also be increased. Accordingly, the electric connection therebetween may be more reliable.

In addition, since the device 800 is brought into contact with the elastic part 540 instead of being brought into contact with the support sheet 520 which is relatively harder, the terminals 801 of the device 800 may be protected. Even though the terminals 801 of the device 800 make contact with sidewalls of the second penetration holes 541 of the elastic part 540 when the device 800 is moved down, the terminals 801 of the device 800 may not be damaged or may be less damaged because the elastic part 540 is formed of a soft material.

The test socket 500 of the current embodiment may be modified as follows.

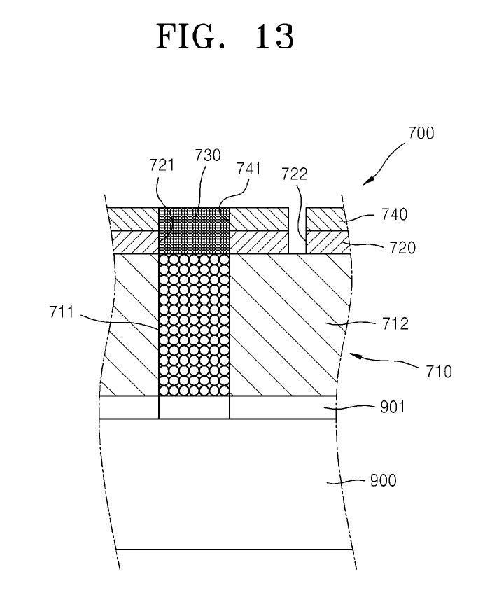

Referring to FIG. 12, a support sheet 620 is disposed on a top surface of an elastic conductive sheet 610, and a lower support sheet 650 corresponding to the support sheet 620 is disposed on a bottom surface of the elastic conductive sheet 610. Lower penetration holes 651 corresponding to first penetration holes 621 of the support sheet 620 are formed in the lower support sheet 650. Lower conduction sections 660 corresponding to second conduction sections 630 may be disposed in the lower penetration holes 651.

Referring to FIG. 13, second conduction sections 730 are inserted into second penetration holes 741 of an elastic part 740. That is, the second conduction sections 730 protruding from the support sheet 720 may be inserted into the second penetration holes 741. In this case, terminals of a device to be tested may be brought into contact with the second conduction sections 730 inserted into the second penetration holes 741.

While the inventive concept has been particularly shown and described with reference to exemplary embodiments thereof, it will be understood that various changes in form and details may be made therein without departing from the spirit and scope of the following claims.

1. A test socket having high-density conduction sections and configured to be disposed between a device to be tested and a test apparatus for electrically connecting terminals of the device and pads of the test apparatus, the test socket comprising:
an elastic conductive sheet comprising first conduction sections and an insulative support section, the first conduction sections being disposed at positions corresponding to the terminals of the device and formed by arranging a plurality of first conductive particles in an elastic material in a thickness direction of first conduction sections, the insulative support section supporting the first conduction sections and insulating the first conduction sections from each other;
a support sheet attached to a top surface of the elastic conductive sheet and comprising penetration holes at positions corresponding to the terminals of the device; and
a second conduction sections disposed in the penetration holes of the support sheet and formed by arranging a plurality of second conductive particles in an elastic material in a thickness direction of thee second conduction sections,
wherein the second conductive particles are arranged more densely than the first conductive particles, and
the penetration holes have an upper diameter that is greater than a lower diameter thereof.

2. The test socket of claim 1, wherein the penetration holes have a downwardly decreasing diameter.

3. The test socket of claim 1, wherein the penetration holes comprise:
diameter decreasing portions having a downwardly decreasing diameter; and
constant diameter portions formed below the diameter decreasing portions and having a constant diameter.

4. The test socket of claim 3, wherein the diameter decreasing portions have a height that is smaller than that of the constant diameter portions.

5. The test socket of claim 1, wherein the second conductive particles have an average particle diameter that is smaller than that of the first conductive particles.

6. The test socket of claim 2, wherein an average distance between the second conductive particles is smaller than an average distance between the first conductive particles.

7. The test socket of claim 1, wherein the support sheet is formed of a material that is harder than a material used to form the insulative support section.

8. The test socket of claim 1, wherein separation lines are formed in the support sheet to provide independency to the second conduction sections neighboring each other.

9. The test socket of claim 8, wherein the separation lines are grooves or holes formed by cutting the support sheet.

10. A test socket having high-density conduction sections and configured to be disposed between a device to be tested and a test apparatus for electrically connecting terminals of the device and pads of the test apparatus, the test socket comprising:
an elastic conductive sheet comprising first conduction sections and an insulative support section, the first conduction sections being disposed at positions corresponding to the terminals of the device and formed by arranging a plurality of first conductive particles in an elastic material in a thickness direction of the first conduction sections, the insulative support section supporting the first conduction sections and insulating the first conduction sections from each other;
a support sheet attached to a bottom surface of the elastic conductive sheet and comprising penetration holes at positions corresponding to the terminals of the device; and
a second conduction sections disposed in the penetration holes of the support sheet and formed by arranging a plurality of second conductive particles in an elastic material in a thickness direction of the second conduction sections,
wherein the second conductive particles are arranged more densely than the first conductive particles, and
the penetration holes have a lower diameter that is greater than an upper diameter thereof.

11. A test socket having high-density conduction sections and configured to be disposed between a device to be tested and a test apparatus for electrically connecting terminals of the device and pads of the test apparatus, the test socket comprising:
an elastic conductive sheet comprising first conduction sections and an insulative support section, the first conduction sections being disposed at positions corresponding to the terminals of the device and formed by arranging a plurality of first conductive particles in an elastic material in a thickness direction of the first conduction sections, the insulative support section supporting the first conduction sections and insulating the first conduction sections from each other;
a support sheet attached to a top surface of the elastic conductive sheet and comprising first penetration holes at positions corresponding to the terminals of the device;
a second conduction sections disposed in the first penetration holes of the support sheet and formed by arranging a plurality of second conductive particles in an elastic material in a thickness direction of the second conduction sections; and
an elastic part disposed on a top surface of the support sheet and comprising second penetration holes corresponding to the terminals of the device, the elastic part being formed of a material that is softer than a material used to form the support sheet,
wherein the second conductive particles are arranged more densely than the first conductive particles.

12. The test socket of claim 11, wherein the second conductive particles have an average particle diameter that is smaller than that of the first conductive particles.

13. The test socket of claim 12, wherein an average distance between the second conductive particles is smaller than an average distance between the first conductive particles.

14. The test socket of claim 11, wherein separation lines are formed in the support sheet to provide independency to the second conduction sections neighboring each other.

15. The test socket of claim 11, wherein the material used to form the support sheet is harder than a material used to form the insulative support section.

16. The test socket of claim 11, wherein the elastic part is formed of the same material as a material used to form the insulative support section.

17. The test socket of claim 11 or 16, wherein the elastic part is formed of silicone rubber.

18. The test socket of claim 11, wherein the terminals of the device are insertable into the second penetration holes of the elastic part.

19. The test socket of claim 11, wherein the second conduction sections protrude from the support sheet and are inserted into the second penetration holes of the elastic part.

20. The test socket of claim 11, further comprising:
a lower support sheet attached to a bottom surface of the elastic conductive sheet and comprising lower penetration holes at positions corresponding to the terminals of the device; and
lower conduction sections disposed in the lower penetration holes of the lower support sheet and formed by arranging a plurality of third conductive particles in an elastic material in a thickness direction of the lower conduction sections,
wherein the third conductive particles are arranged more densely than the first conductive particles.
